(19) United States
(12) Patent Application Publication
(10) Pub. No.: US 2022/0033962 A1
(43) Pub. Date: Feb. 3, 2022

(54) DEPOSITION SYSTEM AND PROCESSING SYSTEM

(71) Applicant: SAMSUNG ELECTRONICS CO., LTD., SUWON-SI (KR)

(72) Inventors: Suhwan Kim, Seoul (KR); Hyunjun Kim, Seoul (KR); Younglim Park, Seoul (KR); Dongkwan Baek, Anyang-si (KR); Hyungsuk Jung, Suwon-si (KR)

(21) Appl. No.: 17/195,900

(22) Filed: Mar. 9, 2021

(30) Foreign Application Priority Data
Jul. 31, 2020 (KR) 10-2020-0095940

(51) Int. Cl. C23C 16/02; C23C 16/448; C23C 16/44; C23C 16/52

(52) U.S. Cl. CPC C23C 16/0245; C23C 16/52; C23C 16/4412; C23C 16/4482

(57) ABSTRACT

A deposition system, includes: a reaction chamber; a first gas supply unit supplying a first precursor in a liquid state stored in a first main tank to the reaction chamber in a gaseous state; a reactant supply unit supplying a reactant to the reaction chamber; and an exhaust unit discharging an exhaust material, wherein the first gas supply unit includes a first sub tank, a first liquid mass flow controller, and a first vaporizer, the first precursor is supplied to the reaction chamber by passing through the first sub tank, the first liquid mass flow controller, and the first vaporizer, a first automatic refill system operates to periodically fill the first sub tank with the liquid first precursor stored in the first main tank, and the exhaust unit comprises a processing chamber, a pump, and a scrubber to which a plasma pretreatment system is applied.

### CROSS-REFERENCE TO RELATED APPLICATION

This application claims priority under 35 U.S.C. § 119 to Korean Patent Application No. 10-2020-0095940, filed on Jul. 31, 2020, in the Korean Intellectual Property Office, the disclosure of which is incorporated by reference herein.

### TECHNICAL FIELD

The present inventive concept relates to a deposition system and a processing system.

### DESCRIPTION OF RELATED ART

A typical method of forming a thin film on a substrate includes Chemical Vapor Deposition (CVD) and Atomic Layer Deposition (ALD). In a CVD and ALD processes, various reactants can be used to form a thin film on a surface of the substrate. In the process, liquid reactants are generally phase-changed to a gaseous state and supplied to a reaction chamber. After a deposition process is completed, exhaust materials of the process are discharged at an exhaust stage. However, when a vaporizer is used to increase the supply of liquid reactants, the replacement cycle of a canister supplying the liquid reactants may be shortened, and the replacement cycle of a pump may be shortened due to the increase of exhaust materials of the process. In addition, the facility operating the deposition system must be stopped when replacing the canister and the pump.

### SUMMARY

An aspect of the present inventive concept provides for a deposition system that facilitates maintenance and management of deposition facilities from a viewpoint of mass production.

According to an aspect of the present inventive concept, a deposition system includes: a reaction chamber; a first gas supply unit configured to supply a liquid first precursor stored in a first main tank to the reaction chamber in a gaseous state; a reactant supply unit configured to supply a reactant, reacting with the first precursor, to the reaction chamber; and an exhaust unit configured to discharge an exhaust material generated from the reaction chamber, wherein the first gas supply unit includes a first sub tank, a first liquid mass flow controller, and a first vaporizer, the first precursor filled in the first sub tank by a first automatic refill system is supplied to the reaction chamber by passing through the first sub tank, the first liquid mass flow controller, and the first vaporizer, the first automatic refill system operates to periodically fill the first sub tank with the first precursor in a liquid state stored in the first main tank, and the exhaust unit comprises a plasma pretreatment system chamber to which a plasma pretreatment system for increasing decomposition rate of the exhaust material is applied, a pump, and a scrubber.

According to an aspect of the present inventive concept, a deposition system includes: a reaction chamber; one or more gas supply units configured to supply at least one precursor to the reaction chamber in a gaseous state; a reactant supply unit configured to supply a reactant, reacting with the precursor to the reaction chamber; and an exhaust unit configured to discharge an exhaust material generated from the reaction chamber, wherein the one or more gas supply units include: a sub tank in which the precursor is stored; a vaporizer for supplying the precursor to the reaction chamber in a gaseous state; and a liquid mass flow controller controlling an amount of the precursor supplied to the vaporizer, the exhaust unit includes a plasma pretreatment system chamber, a pump, and a scrubber, and the plasma pretreatment system chamber exhausts the exhaust material through the pump, after a chemical structure of the exhaust material is changed using the plasma pretreatment system.

According to an aspect of the present inventive concept, a process system includes: at least one automatic refill system configured to fill a sub tank automatically with a process material in a liquid state; a gas supply system configured to supply the process material stored in the sub tank to the reaction chamber in a gaseous state; and a plasma pretreatment system configured to induce plasma discharge to change a chemical structure of an exhaust material discharged from the reaction chamber, wherein the gas supply system is configured to operate a liquid mass flow controller and a vaporizer connected between the sub tank and the reaction chamber, and the liquid mass flow controller is configured to control the amount of the process material supplied to the vaporizer.

### BRIEF DESCRIPTION OF DRAWINGS

The above and other aspects, features, and advantages of the present inventive concept will be more clearly understood from the following detailed description with reference to the accompanying drawings, in which:

FIG. 1 is a schematic block diagram of a deposition system according to an example embodiment of the present inventive concept;

FIGS. 2A to 2C are diagrams illustrating types of reaction chambers in the deposition system according to an example embodiment of the present inventive concept, and specifically, FIG. 2A and FIG. 2C are cross-sectional views of a reaction chamber according to an example embodiment of the present inventive concept;

FIG. 3 is a diagram illustrating an operation of a bubbler in the deposition system according to an example embodiment of the present inventive concept;

FIG. 4 is a diagram illustrating an operation of a vaporizer in a deposition system according to an example embodiment of the present inventive concept;

FIG. 5 is a schematic flowchart illustrating an operation of an automatic refill system in a deposition system according to an example embodiment of the present inventive concept;

FIG. 6 is a schematic diagram illustrating a process of discharging an exhaust material in a deposition system according to an example embodiment of the present inventive concept;

FIG. 7 is a schematic flowchart illustrating an operation of a plasma pretreatment system in a deposition system according to an example embodiment of the present inventive concept; and

FIGS. 8 to 10 are schematic block diagrams of a deposition system according to an example embodiment of the present inventive concept.

### DETAILED DESCRIPTION

Hereinafter, example embodiments of the present inventive concept will be described in detail with reference to the accompanying drawings as follows.

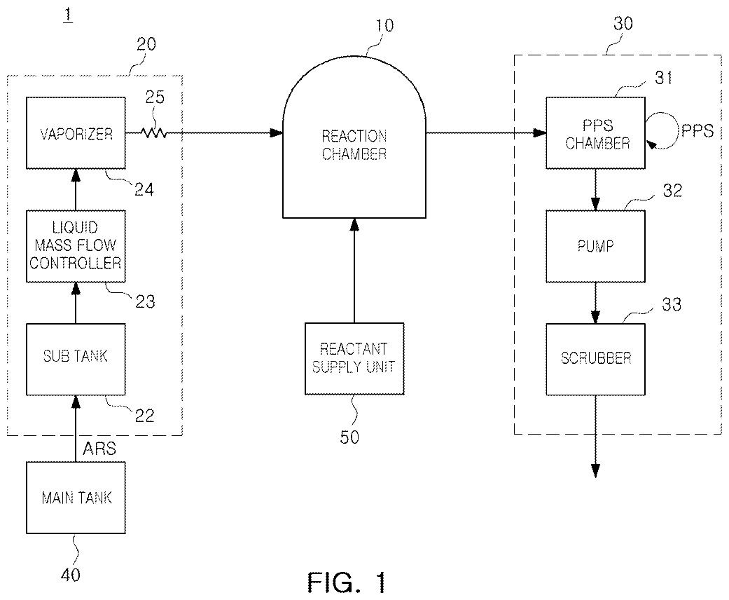

FIG. 1 is a schematic block diagram of a deposition system according to an example embodiment of the present inventive concept.

Referring to FIG. 1, a deposition system 1 may include a reaction chamber 10, a gas supply unit 20, an exhaust unit 30, a main tank 40, and a reaction supply unit 50.

A deposition system 1 according to an example embodiment of the present inventive concept may be a system in which a chemical vapor deposition (CVD) process and/or an atomic layer deposition (ALD) process is performed. The CVD process and the ALD process may be a part of a process for depositing a thin film on a substrate by supplying and reacting a precursor and a reactant into the reaction chamber 10.

A precursor may exist in a liquid or solid state at room temperature, and may be vaporized by a component included in the gas supply unit 20 and supplied to the reaction chamber 10 in a gaseous state. However, this is an example and the present disclosure is not necessarily limited thereto, and the precursor may exist in a gaseous state at room temperature. In the deposition system 1, the precursor may be a liquid reactant. For example, the precursor may be a metal organic precursor, and may be composed of a group 3, 4, or 5 element. However, this is an example embodiment and the present disclosure is not necessarily limited thereto, and the precursor may be composed of other elements.

In a general deposition process, it may be necessary to phase change the liquid precursor into a gaseous state using a vaporizer. For example, a bubbler and/or a vaporizer may be used as a vaporization device for phase-changing a precursor into a gaseous state. For example, a precursor may be phase-changed into a gaseous state using a baking process, and a gaseous precursor may be supplied to the reaction chamber 10 using a carrier gas. Meanwhile, a liquid precursor may be vaporized by bubbling the precursor with a carrier gas, and the gas precursor may be supplied to the reaction chamber 10.

The above-described vaporization devices used in the deposition process may vary, depending on a vapor pressure of the liquid precursor. For example, in the case of a precursor having a low vapor pressure, it may be difficult to vaporize a liquid precursor using a bubbler, and a vaporizer may be required. In the case of a precursor having high vapor pressure, the precursor may be vaporized by a baking process.

When the liquid precursor is phase-changed into a gaseous state using a vaporizer, a larger amount of the precursor may be supplied to the reaction chamber 10 than when a bubbler is used. The amount of the precursor supplied to the reaction chamber 10 may be controlled by a liquid mass flow controller (LMFC).

The precursor supplied to the reaction chamber 10 may be stored in a canister. In some cases, if the precursor is less than a predetermined amount in the canister as the process proceeds, the canister may need to be replaced to proceed with the process again. Accordingly, it may be necessary to stop a process facility to replace the canister. For example, it may be necessary to shut down the process facility to remove impurities from inside a pipe connected to the canister, or to replace the canister.

While the deposition process is in progress and/or after the deposition process is completed, exhaust materials may be discharged to an exhaust end of the reaction chamber 10. As an example, the exhaust materials may include gaseous reactants that did not react during the deposition process or by-products of the reaction. Exhaust materials may be changed into a solid phase and accumulated in a pump 32 connected to the exhaust end of the reaction chamber 10, which may compromise the pump. Accordingly, in order to replace the spent pump, it may be necessary to stop the process facility.

In the deposition system 1 according to an example embodiment of the present inventive concept, the reaction chamber 10 may include a deposition chamber in which a deposition process is performed. For example, the deposition process may be a chemical vapor deposition (CVD) and/or an atomic layer deposition (ALD) process. However, this is an example embodiment and the present disclosure is not necessarily limited thereto, and the reaction chamber 10 of the deposition system 1 according to an example embodiment of the present inventive concept may include a chamber in which another process using gas injection is performed. For example, the reaction chamber 10 may include a polishing process chamber in which cleaning is performed by spraying a cleaning gas after a chemical mechanical polishing (CMP) process, an etching process chamber removing at least a portion of a region of a wafer and/or element layers formed on the wafer by using plasma including radicals and ions of a source gas, or the like. When a process other than the deposition process is performed, the gas supplied to the reaction chamber 10 might not be limited to a precursor.

In the deposition system 1 according to an example embodiment of the present inventive concept, a liquid precursor supplied to the reaction chamber 10 may be stored in a main tank 40. The liquid precursor stored in the main tank 40 may be filled in the gas supply unit 20 by an automatic refill system (ARS). For example, the automatic refill system (ARS) may continuously operate across processes. For example, when the automatic refill system ARS is operated, a negative pressure may be formed in a pipe between the main tank 40 and the gas supply unit 20 by a vacuum pump connected to the pipe. An appropriate amount of a liquid precursor may be filled in the gas supply unit 20 by the formed negative pressure. However, this is an example embodiment and the present disclosure is not necessarily limited thereto, and an operation timing and a method of the automatic refill system ARS may differ according to example embodiments.

In the deposition system 1, the gas supply unit 20 may include a sub tank 22, a liquid mass flow controller 23, and a vaporizer 24. As an example, the gas supply unit 20 may further include a filter 25 for filtering out liquid precursors that have not been completely vaporized in the vaporizer 24. In addition, a plurality of valves for controlling a supply of the precursor may be disposed between and/or within the components of the gas supply unit 20. However, this is an example embodiment and the present disclosure is not necessarily limited thereto, and the number and position of the valves may be determined as necessary.

The sub tank 22 may be filled from the main tank 40 to store a liquid precursor to be used in a corresponding process. As an example, the sub tank 22 may be a canister. The liquid mass flow controller 23 may supply the liquid precursor stored in the sub tank 22 to the vaporizer 24 in a constant amount per unit time. For example, the constant amount per unit time may correspond to a range of about 1 g to 10 g per minute. However, this is an example embodiment and the present disclosure is not necessarily limited thereto, and the amount of supplied liquid precursor may differ depending on the type of liquid precursor, the amount required to proceed with the process, and the number of substrates on which deposition occurs in one process.

The vaporizer 24 may phase-change the liquid precursor into a gaseous state in order to supply the precursor to the reaction chamber 10. The operation of the vaporizer 24 is not limited to one method, and the liquid precursor may be vaporized by operating in various methods according to example embodiments. The gaseous precursor may be supplied to the reaction chamber 10 through the filter 25.

The configuration of the gas supply unit 20 illustrated in FIG. 1 may correspond to an example of vaporizing a liquid precursor using the vaporizer 24 and the liquid mass flow controller 23. In the deposition system 1 according to an example embodiment of the present inventive concept, the gas supply unit 20 may include a bubbler instead of the vaporizer 24 and the liquid mass flow controller 23. The bubbler may be included in a separate configuration, but the present disclosure is not necessarily limited thereto, and may be included in the sub tank 22. The operation of the gas supply unit 20 according to example embodiments of the present inventive concept will be described later.

The reactant supply unit 50 included in the deposition system 1 according to an example embodiment of the present inventive concept may supply a reactant for forming a thin film by reacting with a precursor to the reaction chamber 10. As an example, the supplied reactant may include at least one of H₂O, H₂O₂, O₃, NH₃, and the like. However, this is an example and is not limited thereto, and the reactants supplied according to the example embodiments may be different.

In the deposition system 1 according to an example embodiment of the present inventive concept, during the deposition process and/or after the deposition process is completed, exhaust materials may be discharged to an exhaust end of the reaction chamber 10. The discharged exhaust materials may be discharged from the deposition system 1 through the exhaust unit 30. The exhaust unit 30 may include a plasma pretreatment system (PPS) chamber 31, a pump 32, and a scrubber 33.

Exhaust materials from the deposition process may be discharged through the pump 32 and the scrubber 33 after passing through a plasma pretreatment system (PPS) in the PPS chamber 31. However, the disposition of the PPS chamber 31 is not limited what is illustrated in FIG. 1, and the PPS chamber 31 may be disposed between the pump 32 and the scrubber 33. Meanwhile, a plurality of processing chambers may be installed so that the plasma pretreatment system PPS may be repeatedly applied several times.

A plasma pretreatment system (PPS) applied to the exhaust material in the PPS chamber 31 may supply a reactive gas to the exhaust material. As an example, the reactive gas may be O₂. However, this is an example embodiment and the present disclosure is not necessarily limited thereto, and other reactive gases may be supplied according to example embodiments. Metallic by-products contained in the exhaust material and reactive gases may react to generate products such as zirconia (ZrO₂). For example, zirconia may be in powder form. However, products such as zirconia, or the like, may be stacked on an inner wall of the pipe and obstruct the discharge of exhaust material.

In the deposition system 1 according to an example embodiment of the present inventive concept, the plasma pretreatment system PPS may induce plasma discharge in the PPS chamber 31. Meanwhile, the exhaust material of the deposition process by plasma discharge may be replaced with a material having increased decomposition performance and/or an increased flowability and safety. Accordingly, the plasma pretreatment system PPS can extend a lifespan of the pump 32 and increase an efficiency of the scrubber 33.

For example, when the plasma pretreatment system (PPS) is applied, the lifespan of the pump may be 2 to 3 times that of the pump without the plasma pretreatment system. For example, when the plasma pretreatment system (PPS) is not applied, a replacement cycle of the pump may be 1 month, and when the plasma pretreatment system (PPS) is applied, a replacement cycle of the pump may be 2 months to 3 months. However, this is an example and the present disclosure is not necessarily limited thereto, and the replacement cycle of the pump may differ depending on the process environment, the performance of the plasma pretreatment system (PPS), the performance of the pump, and the like.

In the deposition system 1 according to an example embodiment of the present inventive concept, the exhaust material discharged to the exhaust end of the reaction chamber 10 may contain materials in various states. The pump 32 may discharge exhaust material using negative pressure. The scrubber 33 may serve to dissolve and absorb the exhaust materials in a gaseous state. However, this is an example embodiment and the present disclosure is not necessarily limited thereto, and various methods for safely discharging and discharging the exhaust material may be applied to the exhaust unit 30, and additional components necessary for this may be further included.

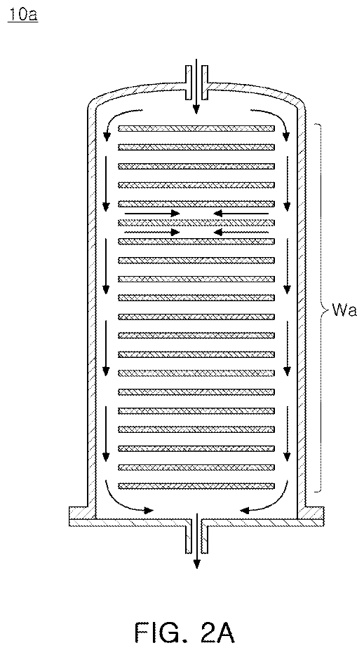

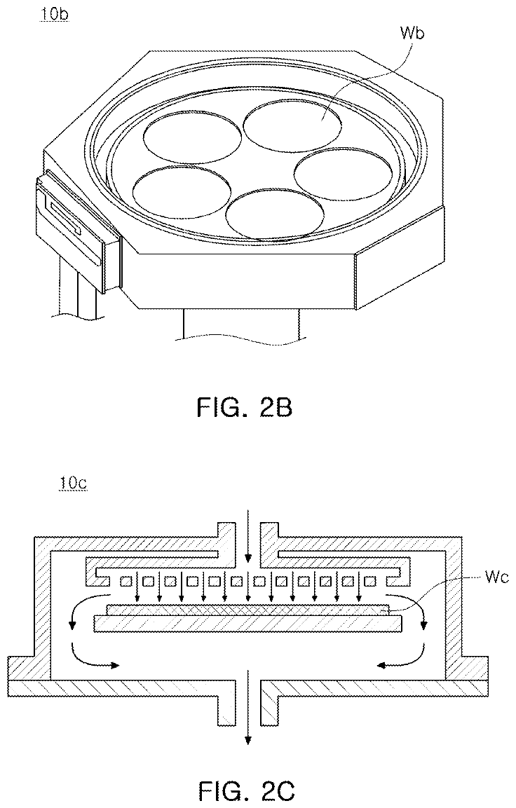

FIGS. 2A to 2C are diagrams for explaining types of reaction chambers in the deposition system according to an example embodiment of the present inventive concept.

Referring to FIGS. 2A to 2C, in the deposition system according to an example embodiment of the present inventive concept, a reaction chamber may be a deposition chamber in which a deposition process of depositing a thin film on the upper surface of a substrate is performed. The deposition chamber may be classified into a batch type, a semi-batch type, and/or a single type according to the number of substrates on which processes are simultaneously performed. For example, the substrate on which the deposition process is performed may be wafers Wa, Wb, and Wc. However, a process target might not be limited to the wafers Wa, Wb, and Wc according to example embodiments. For example, various substrates other than the wafers Wa, Wb, and Wc, such as a mother substrate for a display, may be a process target.

The deposition system according to an example embodiment of the present inventive concept may be applied regardless of reaction chamber type. For example, in the past, the batch type reaction chamber was mainly used to increase process speed, but in recent years, single type reaction chambers are increasing in use to increase process accuracy, and accordingly maintenance and management of facilities are becoming more important. The deposition system according to an example embodiment of the present inventive concept makes it easier to maintain and manage the facility, and can increase process efficiency.

Referring to FIG. 2A, a reaction chamber 10a in which a process is performed may have a batch type. For example, the batch type reaction chamber 10a may simultaneously process a plurality of wafers Wa. For example, a precursor in a gaseous state supplied to the reaction chamber 10a may deposit a thin film on upper surfaces of the wafers Wa disposed in a specific arrangement. However, the reaction chamber and associated processes are not limited to the example embodiment shown in FIG. 2A, and the internal shape of the batch type reaction chamber 10a may differ according to an example embodiment.

Referring to FIG. 2B, a reaction chamber 10b in which a process is performed may have a semi-batch type. For example, the semi-batch type reaction chamber 10b may simultaneously process a plurality of wafers Wb. For example, a precursor in a gaseous state supplied to the reaction chamber 10b may deposit a thin film on upper surfaces of the wafers Wb disposed in a specific arrangement. However, the reaction chamber and associated processes are not limited to the example embodiment shown in FIG. 2B, and the internal shape of the semi-batch type reaction chamber 10b may differ according to an example embodiment.

For example, the number of wafers Wb able to be simultaneously processed in the semi-batch type reaction chamber 10b may be less than the number of wafers Wa able to be simultaneously processed in the batch type reaction chamber 10a shown in FIG. 2A. However, compared to the batch type reaction chamber 10a, the semi-batch type reaction chamber 10b may increase the accuracy of the precision process.

Referring to FIG. 2C, a reaction chamber 10c in which a process is performed may have a type referred to as a “single type”. For example, the single type reaction chamber 10c may process one wafer Wc at a time. Although the single type reaction chamber 10c may have a slower process speed compared to the batch type reaction chamber 10a, a thin film can be uniformly deposited on an upper surface of the wafer Wc using a high degree of precision. However, is the reaction chamber and associated processes are not limited to the example embodiment shown in FIG. 2C, and the internal shape of the single type reaction chamber 10b may differ according to an example embodiment.

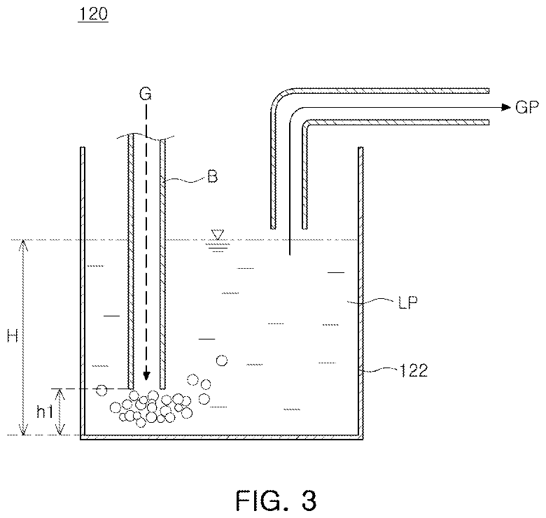

FIG. 3 is a diagram illustrating an operation of a bubbler in the deposition system according to an example embodiment of the present inventive concept.

Referring to FIG. 3, in the deposition system according to an example embodiment of the present inventive concept, a sub tank 122 included in the gas supply unit 120 may include a bubbler B for vaporizing a liquid precursor LP and supplying the liquid precursor LP in a gaseous state to the reaction chamber. The bubbler B may be included in the gas supply unit 120 as a separate device from the sub tank 122.

For example, the sub tank 122 may be filled with a liquid precursor LP to a predetermined height H. The bubbler B may inject carrier gas G at a first height h1. For example, the first height h1 may be lower than a predetermined height H filled with the liquid precursor LP. Accordingly, the carrier gas G may be directly injected into the liquid precursor LP. For example, the carrier gas G may be a gas such as N₂ having low reactivity. However, this is an example embodiment and the present disclosure is not necessarily limited thereto, and various carrier gases G may be used according to example embodiments.

Meanwhile, a bubbling may occur in the liquid precursor LP by the injection of the carrier gas G, and the liquid precursor LP may be vaporized into a gas precursor GP. The gas precursor GP may be supplied to the reaction chamber through a pipe. For example, an inlet of the pipe through which the gas precursor GP exits may be disposed above a surface of the liquid precursor LP. However, this is an example and the present disclosure is not necessarily limited thereto, and the inlet of the pipe may be disposed close to the surface of the liquid precursor LP, or it may be disposed in various ways through which the gas precursor GP may escape.

The liquid precursor LP in which the bubbling may occur may be a material having a predetermined vapor pressure. For example, in the case of a deposition process using a liquid precursor LP having a vapor pressure of about 1 Torr or more at 100° C., the liquid precursor LP may be vaporized using a bubbler B. However, this is an example and the present disclosure is not necessarily limited thereto, and even in a deposition system using a liquid precursor LP having a high vapor pressure, a vaporizer to be described later may be used instead of the bubbler B to increase the amount of precursor supplied.

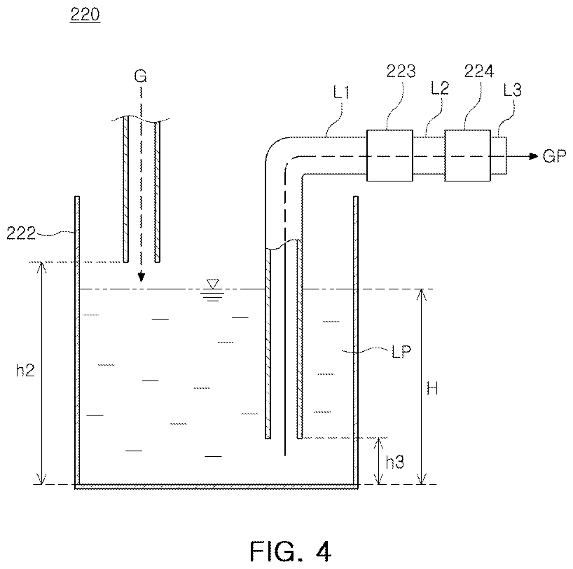

FIG. 4 is a diagram illustrating an operation of a vaporizer in a deposition system according to an example embodiment of the present inventive concept.

Referring to FIG. 4, in the deposition system according to an example embodiment of the present inventive concept, the gas supply unit 220 may include a liquid mass flow controller 223, a vaporizer 224, and a sub tank 222. The liquid mass flow controller 223 may adjust an amount of the liquid precursor LP supplied to the vaporizer 224. The vaporizer may vaporize the liquid precursor LP supplied from the liquid mass flow controller 223 and supply it to the reaction chamber in a gas precursor (GP) state.

For example, the sub tank 222 may be filled with a liquid precursor LP to a predetermined height H. In order to supply the liquid precursor LP to the liquid mass flow controller 223, a carrier gas G may be injected at a second height h2 of the sub tank 222. For example, the second height h2 may be higher than a predetermined height H filled with the liquid precursor LP. Accordingly, the carrier gas G may be injected onto the surface of the liquid precursor LP.

A part of the liquid precursor LP may be supplied to the liquid mass flow controller 223 along a first pipe L1 by injection of the carrier gas G. For example, an inlet of the first pipe L1 may be disposed at a third height h3, lower than a predetermined height H filled with the liquid precursor LP. However, this is an example embodiment and the arrangement of the first pipe L1 might not be limited thereto.

The liquid precursor LP may be supplied to the vaporizer 224 along a second pipe L2 at an amount controlled by the liquid mass flow controller 223. The gas precursor GP phase-changed into a gaseous state using the vaporizer 224 may be supplied to the reaction chamber along the third pipe L3. Accordingly, the precursor passing through the first pipe L1 and the second pipe L2 may be a liquid precursor LP, and the precursor passing through the third pipe L3 may be a gas precursor GP.

In the deposition system according to an example embodiment of the present inventive concept, the liquid precursor LP using the vaporizer 224 may be a material having a low vapor pressure. However, this is an example and the present disclosure is not limited thereto, the vaporizer 224 may be used to increase the supply of the gas precursor GP regardless of the precursor's vapor pressure.

Referring to FIGS. 3 and 4, in the deposition system according to an example embodiment of the present inventive concept, a bubbler or vaporizer for vaporizing a precursor may work with other components to operate as a whole system. However, this is an example embodiment, and the present disclosure is not necessarily limited thereto, and the bubbler or vaporizer may be operated by a separate system regardless of the operation of other components. For example, the bubbler or vaporizer may be operated by a separate gas supply system.

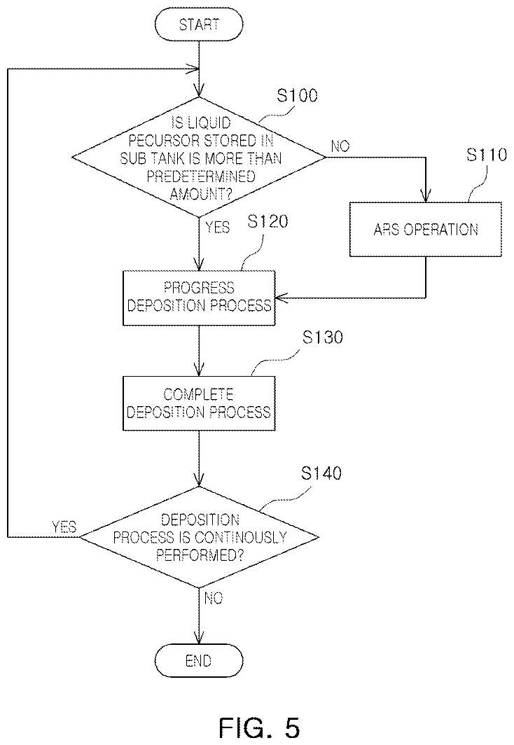

FIG. 5 is a schematic flowchart illustrating operation of an automatic refill system in a deposition system according to an example embodiment of the present inventive concept.

Referring to FIG. 5, in the deposition system, a liquid precursor may be filled from a main tank to a sub tank by applying an automatic refill system. For example, the automatic refill system may determine whether the liquid precursor filled in the sub tank is greater than or equal to a predetermined amount (S100). The predetermined amount may be an amount of the liquid precursor required to proceed with the next process. However, this is an example embodiment and the present disclosure is not necessarily limited thereto, and the sub tank may be further filled with a liquid precursor to an amount in excess of the amount required by the process.

When the liquid precursor filled in the sub tank is less than a predetermined amount, an automatic refill system may be operated to fill the liquid precursor stored in the main tank into the sub tank (S110). For example, a vacuum pump may be disposed between the main tank and the sub tank, and the liquid precursor may be automatically filled using a negative pressure formed by the vacuum pump. When the liquid precursor filled in the sub tank is greater than or equal to a predetermined amount, the above-described deposition process may be performed (S120).

After the deposition process is completed (S130), it is determined whether to continue the deposition process (S140), and if so, the deposition process may be repeated again from the step S100.

In the automatic refill system applied to the deposition system according to an example embodiment of the present inventive concept, instead of continuously replacing the canister, a deposition process may be performed by filling the liquid in a sub tank. Thereby, process efficiency may be increased by utilizing a period of facility shutdown that may otherwise be spent replacing the canister as an operating period.

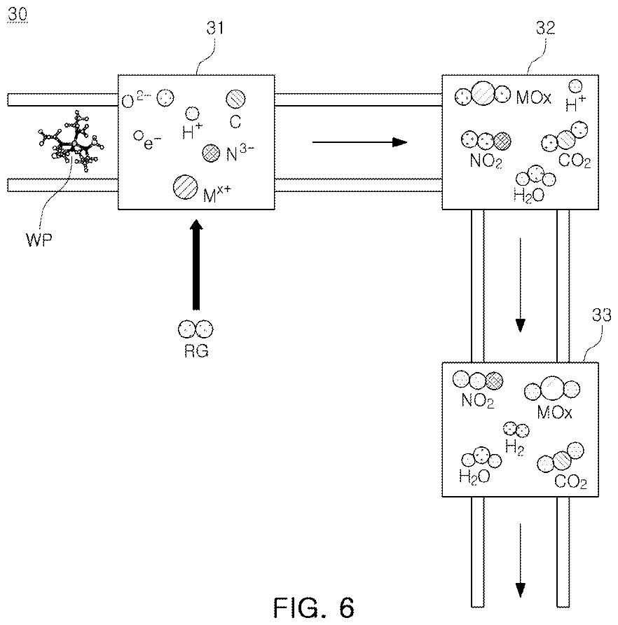

FIG. 6 is a schematic diagram illustrating a process of discharging an exhaust material in a deposition system according to an example embodiment of the present inventive concept.

Referring to FIG. 6, in the deposition system according to an example embodiment of the present inventive concept, exhaust materials WP generated in the deposition process may be discharged to the exhaust unit 30 through an exhaust end of the reaction chamber.

As an example, the exhaust unit 30 may include a PPS chamber 31, a pump 32, and a scrubber 33 that applies a plasma pretreatment system (PPS) for changing the chemical structure of the exhaust material WP.

In the deposition system, the plasma pretreatment system may facilitate discharge by decomposing and/or replacing the exhaust material WP discharged from the reaction chamber. As an example, the plasma pretreatment system may be applied to the exhaust material WP in the PPS chamber 31. However, the plasma pretreatment system is not limited to being applied to the deposition system, and may be applied not only to the deposition process but also to other processes for discharging the exhaust material WP. For example, the plasma pretreatment system may be applied to processes such as ashing, etching, annealing, and cleaning.

The exhaust material WP before the plasma pretreatment system is applied may be a precursor that has not yet reacted and/or a by-product remaining after the reaction. For example, the exhaust material WP may be a material having a relatively complex structure, such as zirconia. Accordingly, when the exhaust material WP is discharged without the application of the plasma pretreatment system, a lifespan of the pump 32 may be shortened due to issues such as excessive force on the pump 32 or accumulation of the exhaust material WP in the pipe.

A plasma pretreatment system may be applied to the PPS chamber 31. The plasma pretreatment system may include supplying a reactive gas (RG) and inducing plasma discharge. For example, the reactive gas RG may be O₂. Exhaust materials with increased decomposition rates due to the plasma discharge may be decomposed into ions having charges. For example, the exhaust materials to which the plasma pretreatment system is applied may include N³⁻, O²⁻, H⁺, M^{x+}, C, e⁻ (electrons), and the like. However, this is an example embodiment and the present disclosure is not necessarily limited thereto, and the operation of the plasma pretreatment system and the decomposed exhaust materials differ according to the example embodiments.

The exhaust materials in an ionic state moved to the pump 32 may be recombined to form a new material. For example, the pump 32 may include mixed oxides (MO_{X}), NO₂, H₂O, CO₂, and the like. However, this is only an example and the present disclosure is not necessarily limited thereto, and in addition, various materials may be included. For example, the pump 32 may include H⁺ (cations) that are not recombined.

The scrubber 33 may dissolve and discharge at least some of the remaining exhaust materials. Meanwhile, since the exhaust materials to which the plasma pretreatment system is applied are decomposed and/or substituted with a material having a relatively simple structure compared to the initial exhaust material WP, the efficiency of the scrubber 33 may be increased. For example, the exhaust material discharged to the outside through the scrubber 33 may be in the form of MO_{X}, NO₂, H₂O, CO₂, H₂, or the like. However, this is an example and the present inventive concepts are not necessarily limited thereto, and various materials may be included.

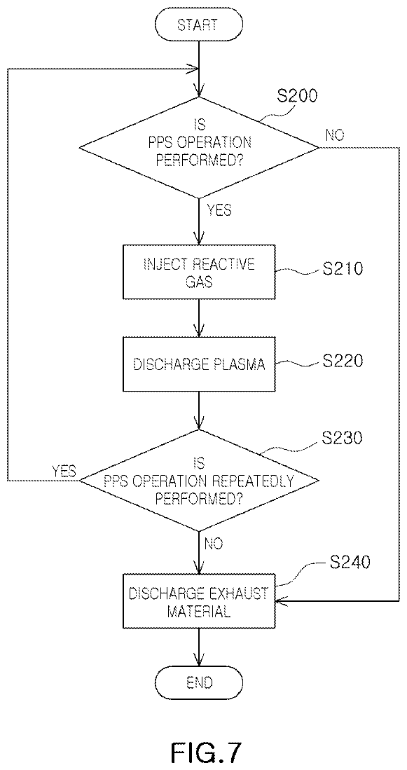

FIG. 7 is a schematic flowchart illustrating an operation of a plasma pretreatment system in a deposition system according to an example embodiment of the present inventive concept.

Referring to FIG. 7, the plasma retreatment system operation might not always be performed in every process. Therefore, the deposition system according to an example embodiment of the present inventive concept may determine whether to operate a plasma pretreatment system at step S200. The plasma pretreatment system may operate during and/or between processes. When the plasma pretreatment system is not operated, an exhaust material discharged from the reaction chamber may be discharged to the outside through a pump and a scrubber.

When the plasma pretreatment system is operated, a reactive gas may be injected into the processing chamber (S210). For example, as described above, a reactive gas may be O₂. The reactive gas may be decomposed by reacting with the exhaust material discharged from the reaction chamber.

However, since an exhaust material in a form of powder that has not completely decomposed may accumulate in the pump and can shorten the lifespan of the pump, plasma discharge may be used to increase decomposition performance (S220). For example, the plasma discharge may be generated in the form of an RF plasma discharge. However, this is an example embodiment and the present disclosure is not necessarily limited thereto, and may be generated in a form of DC glow discharge or the like according to example embodiments.

In the deposition system, the plasma pretreatment system may be operated multiple times according to an example embodiment. Therefore, a step S230 of determining whether to repeatedly operate the plasma pretreatment system may be performed. Accordingly, steps S210 and S220 may be repeated multiple times. The exhaust material with increased decomposition performance by the above-described steps may be discharged through a pump and a scrubber (S240). However, as described above, this is an example embodiment and the present disclosure is not necessarily limited thereto, and the configuration of the exhaust unit and the disposition of each component may vary according to an example embodiment.

The plasma pretreatment system applied to the deposition system may operate to discharge the exhaust material with increased decomposition performance. Accordingly, it is possible to extend the lifespan of the pump by reducing the amount of exhaust material accumulated in the pump. In addition, the exhaust efficiency can be increased by increasing the efficiency of the scrubber.

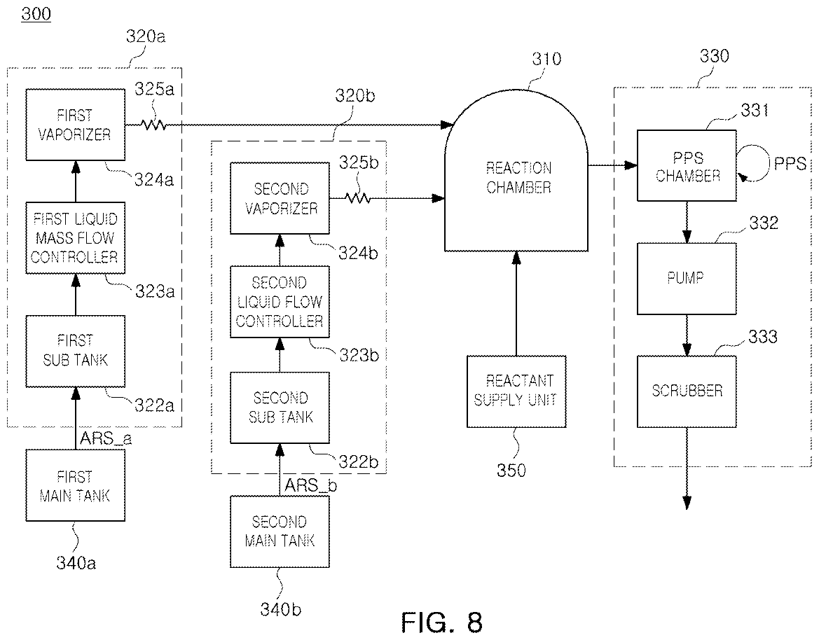

FIGS. 8 to 10 are schematic block diagrams of a deposition system according to an example embodiment of the present inventive concept.

Referring to FIG. 8, a deposition system 300 according to an example embodiment of the present inventive concept may be a deposition system when a thin film to be deposited is made of a binary material or a ternary material. Accordingly, in addition to the first gas supply unit 320a corresponding to the gas supply unit 20, a second gas supply unit 320b may be further included. The deposition system 300 may include components corresponding to the respective components illustrated in the deposition system 1 of FIG. 1.

The first precursor, which is a component of the thin film to be deposited, may be filled in the first gas supply unit 320a from the first main tank 340a by the first automatic refill system ARS_a. The first gas supply unit 320a may supply a first precursor in a gaseous state to the reaction chamber 310, and the second gas supply unit 320b may supply a second precursor different from the first precursor to the reaction chamber 310 in a gaseous state.

In the deposition system 300 according to an example embodiment of the present inventive concept, the second gas supply unit 320b may include components corresponding to the first gas supply unit 320a. As an example, the second gas supply unit 320b may include a second sub tank 322b, a second liquid mass flow controller 323b, a second vaporizer 324b, and a second filter 325b. The second sub tank 322b may store the second precursor filled by the second automatic refill system ARS_b from the second main tank 340b.

The first precursor and the second precursor may react with a reactant supplied from the reactant supply unit 350 in the reaction chamber 310 to form a thin film on a substrate. Exhaust materials discharged by the deposition process may be discharged to the outside after the plasma pretreatment system shown in FIG. 6 is applied. Other features and operations of the configuration may be the same as the deposition system 1 shown in FIG. However, this is an example and the present disclosure is not necessarily limited thereto, and the configurations of the first gas supply unit 320a and the second gas supply unit 320b may vary according differences in physical properties between the first precursor and the second precursor.

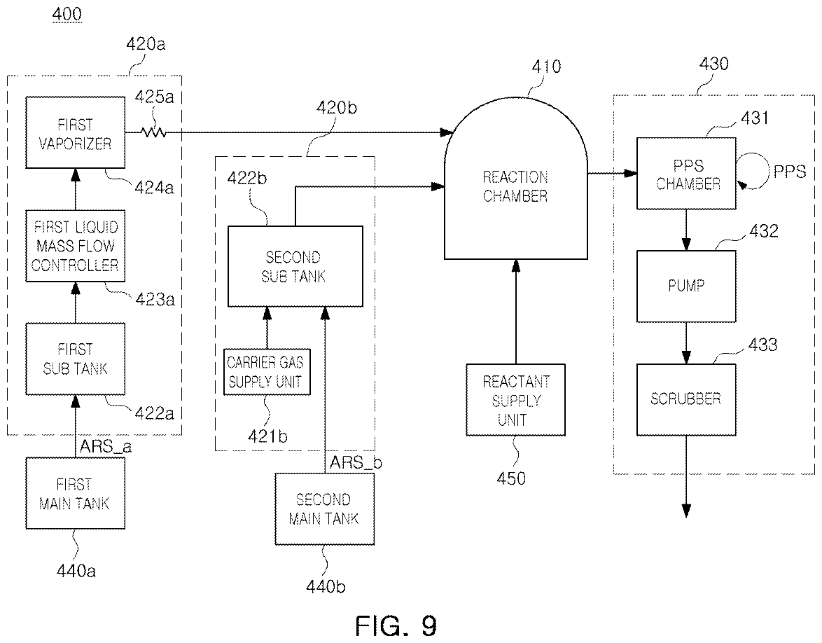

Referring to FIG. 9, the deposition system 400 according to an example embodiment of the present inventive concept may be a deposition system when a thin film to be deposited is made of a binary material or a ternary material. For example, the deposition system 400 may further include a second gas supply unit 420b, together with a first gas supply unit 420a corresponding to the gas supply unit 20 illustrated in the deposition system 1 of FIG. 1.

The first precursor, which is a component of the thin film to be deposited, may be filled in the first gas supply unit 420a from the first main tank 440a by the first automatic refill system ARS_a. The first gas supply unit 420a may supply a first precursor in a gaseous state to the reaction chamber 410. The second precursor, different from the first precursor, may be filled in the second sub tank 422b by the second automatic refill system ARS_b from the second main tank 440b. The second gas supply unit 420b may supply a second precursor to the reaction chamber 410 in a gaseous state.

The second gas supply unit 420b included in the deposition system 400 may vaporize a second vaporizer by using a bubbler, unlike the second gas supply unit 320b included in the deposition system 300 shown in FIG. 8. For example, the carrier gas supply unit 421b may supply a carrier gas to the second sub tank 422b. For example, the carrier gas may be a gas such as N₂ having low reactivity. The liquid second precursor stored in the second sub tank 422b may be vaporized by a baking process and/or bubbling and supplied to the reaction chamber 410.

The first precursor and the second precursor may react with the reactant supplied from the reactant supply unit 450 in the reaction chamber 410 to form a thin film on the substrate. Exhaust materials discharged by the deposition process may be discharged to the outside after the plasma pretreatment system shown in FIG. 6 is applied.

Other features and operations of the configuration may be the same as the deposition system 1 shown in FIG . However, this is an example and the present disclosure is not necessarily limited thereto, and the configurations of the first gas supply unit 420a and the second gas supply unit 420b may have different characteristics according to differences in physical properties between the first precursor and the second precursor.

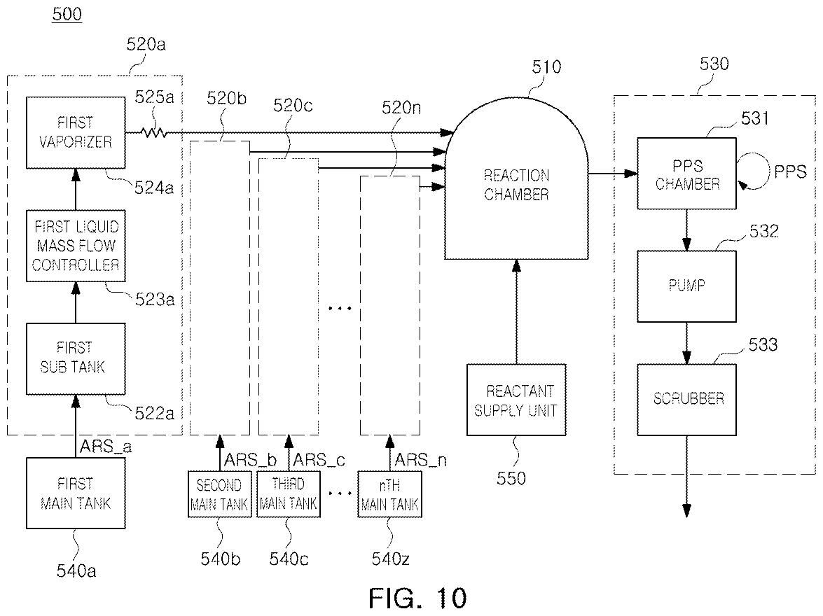

Referring to FIG. 10, a deposition system 500 according to an example embodiment of the present inventive concept may further include a plurality of gas supply units (520b, 520c, . . . 520n), together with the first gas supply unit 520a corresponding to the gas supply unit 20 illustrated in the deposition system 1 of FIG. 1. For convenience of description, at least a portion of the deposition system 500 shown in FIG. 10 may be the same as the deposition system 300 shown in FIG. 8 and/or the deposition system 400 shown in FIG. 9.

The first gas supply unit 520a may supply a first precursor in a gaseous state to the reaction chamber 510. The n-th gas supply unit may supply the n-th precursor in a gaseous state to the reaction chamber 510.

The number of gas supply units 520a, 520b, . . . 520n and a reactant supply unit 550 may be determined by the composition of the thin film deposited on the substrate. For example, in the case of a thin film composed of a binary material, a deposition process may be performed by a deposition system including one gas supply unit 520a and a reactant supply unit 550. In addition, in the case of a thin film made of a ternary material, a deposition process may be performed by a deposition system including two gas supply units 520a and 520b and a reactant supply unit 550. However, this is an example embodiment and the present disclosure not necessarily limited thereto, and the number of constituent elements of the thin film, the number of gas supply units 520a, 520b, . . . 520n, and the number of reactant supply units 550 may be different depending on the deposition process method.

Each of the plurality of gas supply units 520a, 520b, . . . 520n may include independent components, respectively. For example, the plurality of gas supply units 520a, 520b, . . . 520n may all be gas supply units including a vaporizer, similar to the deposition system illustrated in FIG. 1. However, the present inventive concept is not necessarily limited thereto, and one or more of the gas supply units of the plurality of gas supply units 520a, 520b, . . . 520n may be a gas supply unit including a bubbler.

In the deposition system according to an example embodiment of the present inventive concept, the first to n-th precursors respectively supplied from the n gas supply units 520a, 520b, . . . 520n may react with the reactants supplied from the reactant supply unit 550 to form a thin film on a substrate.

The exhaust materials discharged by the deposition process may be discharged to the outside after the plasma pretreatment system shown in FIG. 6 is applied. Other features and operations of the configuration may be the same as the deposition system 1 shown in FIG. 1. However, this is an example embodiment and the present disclosure is not necessarily limited thereto, and configurations of the first gas supply unit 520a to the n-th gas supply unit 520n may have different characteristics according to differences in physical properties of the first to n-th precursors.

As set forth above, a deposition system may use an Auto Refill System (ARS) applied to a sub tank instead of periodically replacing a canister, thereby maintaining a liquid reactant solution in a state that may be supplied without interruption. In addition, by applying a plasma pretreatment system (PPS) to an exhaust unit, a lifespan of a pump can be increased and an efficiency of a scrubber can be increased.

It can be understood that when an element is referred to with terms such as “first” and “second”, the element is not limited thereby. They may be used for the purpose of distinguishing the element from the other elements, and might not limit the sequence or importance of the elements. In some cases, a first element may be referred to as a second element without departing from the scope of the claims set forth herein. Similarly, a second element may also be referred to as a first element.

The term “an example embodiment” used herein does not refer to the same example embodiment, and is provided to emphasize a particular feature or characteristic different from that of another example embodiment. However, example embodiments provided herein are considered to be able to be implemented by being combined in whole or in part one with one another. For example, one element described in a particular example embodiment, even if it is not described in another example embodiment, may be understood as a description related to another example embodiment, unless an opposite or contradictory description is provided therein.

Terms used herein are used in order to describe an example embodiment rather than limiting the present disclosure. In this case, singular forms include plural forms unless interpreted otherwise in context.

While example embodiments have been shown and described above, it will be apparent to those skilled in the art that modifications and variations could be made without departing from the scope of the present inventive concept.

1. A deposition system, comprising:
a reaction chamber;
a first gas supply unit configured to supply a first precursor in a liquid state stored in a first main tank to the reaction chamber in a gaseous state;
a reactant supply unit configured to supply a reactant, reacting with the first precursor, to the reaction chamber; and
an exhaust unit configured to discharge an exhaust material from the reaction chamber,
wherein the first gas supply unit comprises a first sub tank, a first liquid mass flow controller, and a first vaporizer,
wherein the first precursor filled in the first sub tank by a first automatic refill system is supplied to the reaction chamber by passing through the first sub tank, the first liquid mass flow controller, and the first vaporizer,
wherein the first automatic refill system forms a negative pressure in a pipe between the first main tank and the first gas supply unit, and periodically fills the first sub tank with the first precursor in a liquid state stored in the first main tank to maintain a state in which the first precursor can be supplied to the reaction chamber, and
wherein the exhaust unit comprises a plasma pretreatment system chamber to which a plasma pretreatment system for increasing decomposition rate of the exhaust material is applied, a pump, and a scrubber.

2. The deposition system of claim 1, wherein the first liquid mass flow controller is configured to supply the first precursor to the first vaporizer in a constant amount per unit time.

3. The deposition system of claim 1, further comprising a second gas supply unit supplying a second precursor in a liquid state stored in a second main tank to the reaction chamber in a gaseous state,
wherein the second gas supply unit comprises a second sub tank storing the second precursor, and
wherein the second precursor is different from the first precursor.

4. The deposition system of claim 3, wherein the second gas supply unit is configured to supply the second precursor to the reaction chamber through a separate path, different from the first gas supply unit.

5. The deposition system of claim 3, wherein a second automatic refill system operating separately from the first automatic refill system is applied to the second gas supply unit, and
wherein the second automatic refill system periodically fills the second sub tank with the second precursor in a liquid state stored in the second main tank.

6. The deposition system of claim 3, wherein the second gas supply unit further comprises a vaporization device, wherein the vaporization device is either a bubbler or a vaporizer,
wherein the vaporization device is determined according to a vapor pressure of the second precursor and a required supply amount of the second precursor, and
wherein the second precursor vaporized by the determined vaporization device is supplied to the reaction chamber.

7. The deposition system of claim 3, wherein the second gas supply unit further comprises a second liquid mass flow controller, and a second vaporizer, which are sequentially connected between the second sub tank and the reaction chamber,
wherein the second liquid mass flow controller is configured to adjust a flow rate of the second precursor and to supply the second precursor to the second vaporizer, and
the second vaporizer is configured to vaporize the second precursor and to supply the second precursor to the reaction chamber.

8. The deposition system of claim 3, wherein the second gas supply unit further comprises a carrier gas supply unit and a bubbler,
wherein the carrier gas supply unit is configured to inject a carrier gas into the second sub tank,
wherein the bubbler is configured to generate bubbling using the carrier gas, and
wherein the second precursor vaporized by the bubbling is supplied to the reaction chamber.

9. The deposition system of claim 8, wherein a vapor pressure of the second precursor is 1 Torr or more at 100° C.

10. The deposition system of claim 3, wherein the second gas supply unit further comprises a carrier gas supply unit,
wherein the carrier gas supply unit is configured to inject a carrier gas into the second sub tank, and
wherein the second precursor vaporized by a baking process is supplied to the reaction chamber.

11. The deposition system of claim 1, wherein the first gas supply unit further comprises a filter disposed between the first vaporizer and the reaction chamber.

12. The deposition system of claim 1, wherein the reaction chamber is a batch type, a semi-batch type, or a single type.

13. The deposition system of claim 1, wherein the plasma pretreatment system is configured to supply a reactive gas to the exhaust material, and then to induce plasma discharge.

14. A deposition system, comprising:
a reaction chamber;
one or more gas supply units respectively configured to supply one or more precursors to the reaction chamber in a gaseous state;
a reactant supply unit configured to supply a reactant, reacting with the one or more precursors, to the reaction chamber; and
an exhaust unit configured to discharge an exhaust material from the reaction chamber,
wherein the one or more gas supply units comprise: a sub tank to which an automatic refill system forming a negative pressure in a pipe between a main tank and the gas supply unit and periodically filling the precursor to maintain a state in which the precursor can be supplied to the reaction chamber is applied; a vaporizer for supplying the precursor to the reaction chamber in a gaseous state; and a liquid mass flow controller controlling an amount of the precursor supplied to the vaporizer,
wherein the exhaust unit comprises a plasma pretreatment system chamber, a pump, and a scrubber, and
wherein the plasma pretreatment system chamber exhausts the exhaust material through the pump, after a plasma pretreatment system is applied, wherein the plasma pretreatment system changes a chemical structure of the exhaust material.

15. The deposition system of claim 14, wherein the automatic refill system is configured to fill the sub tank automatically with the precursor between a first process using the precursor and a second process performed after the first process.

16. The deposition system of claim 14, wherein the plasma pretreatment system is controlled to selectively operate as needed, independent of a process in the reaction chamber.

17. A process system, comprising:
at least one automatic refill system configured to form a negative pressure in a pipe connected to a main tank storing a process material in liquid state to fill a sub tank automatically with the process material, and to maintain the process material stored in the sub tank above a certain amount;
a gas supply system configured to supply the process material stored in the sub tank to the reaction chamber in a gaseous state,
a plasma pretreatment system configured to induce plasma discharge to change a chemical structure of an exhaust material discharged from the reaction chamber,
wherein the gas supply system is configured to operate a liquid mass flow controller and a vaporizer connected between the sub tank and the reaction chamber, and
wherein the liquid mass flow controller is configured to control an amount of the process material supplied to the vaporizer.

18. The process system of claim 17, wherein the process material is used in one of a deposition process, an etching process, an ashing process, an annealing process and a cleaning process, and
wherein the gas supply system is configured to periodically supply the process material in a gaseous state to the reaction chamber.

19. The process system of claim 17, wherein the gas supply system comprises a plurality of gas supply units, and
wherein the plurality of gas supply units are configured to supply a plurality of process materials to the reaction chamber, respectively.

20. The process system of claim 19, wherein at least two of the plurality of gas supply units are configured to operate by different mechanisms.
